(19) United States
(12) Patent Application Publication
(10) Pub. No.: US 2021/0183758 A1
(43) Pub. Date: Jun. 17, 2021

(54) CONDUCTIVE POLYGON POWER AND GROUND INTERCONNECTS FOR INTEGRATED-CIRCUIT PACKAGES

(71) Applicant: Intel Corporation, Santa Clara, CA (US)

(72) Inventors: Mohd Muhaiyiddin Bin Abdullah, Kepala Batas (MY); Lee Ping Loh, Georgetown (MY); Pheak Ti Teh, Tanjung Bungah (MY); Ken Beng Lim, Bayan Lepas (MY)

(21) Appl. No.: 17/030,080

(22) Filed: Sep. 23, 2020

(30) Foreign Application Priority Data
Dec. 16, 2019 (MY) PI 2019007505

(51) Int. Cl. H01L 23/498; H01L 23/64; H01L 21/48

(52) U.S. Cl. CPC H01L 23/49838; H01L 23/642; H01L 23/49816; H01L 21/4867; H01L 23/49822; H01L 23/49833

(57) ABSTRACT

Disclosed embodiments include conductive polygon power and ground interconnects in an infield formed by an electrical contact array. The conductive polygon ground interconnects are orthogonally reticulated an among the conductive polygon power interconnects, for integrated-circuit device packages that provide a low-loss path to active and passive devices, by minimizing resistive loops.

### PRIORITY APPLICATION

This application claims the benefit of priority to Malaysian Application Serial Number PI2019007505, filed Dec. 16, 2019, which is incorporated herein by reference in its entirety.

### FIELD

This disclosure relates to providing power delivery with a smoothed second and third droop during operation of integrated-circuit devices within integrated-circuit device packages.

### BACKGROUND

Signal and power integrity is challenging for complex packaging of integrated-circuit components coupled to packages and boards. Challenges include such issues as second and third droops during power delivery that hinder utility.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1 is a perspective elevation of an integrated-circuit package substrate with selected conductive polygon interconnects according to several embodiments;

FIG. 2 is a schematic design of a region on an interconnect surface of an integrated-circuit package substrate with a primary conductive polygon interconnect and two conductive polygon Vss interconnects according to an embodiment;

FIG. 2A represents a conventional design layout of Vcc and Vss in an integrated-circuit package substrate while FIG. 2B illustrates a disclosed design layout where Vcc and Vss were design as conductive polygon interconnects in an integrated-circuit package substrate;

FIG. 3A illustrates conventional Vcc, Vss and other interconnect balls in an integrated-circuit package substrate;

FIG. 3B illustrates a disclosed design layout where Vcc and Vss were designed as conductive polygon interconnects and at least one passive device that bridges between respective power and ground conductive polygon interconnect in an integrated-circuit package substrate;

FIGS. 4A and 4B illustrate details of at least one passive device that bridges between respective power and ground conductive polygon interconnects according to an embodiment;

FIG. 5 is a land side plan of an integrated-circuit package substrate that carries a conductive polygon interconnect according to an embodiment;

FIGS. 6A through 6D illustrate a process-flow for assembling a conductive polygon interconnect among a ball-grid array on an integrated-circuit package substrate according to several embodiments;

FIG. 7A is a cross-section elevation of an integrated-circuit package and a printed wiring board assembly that includes a conductive polygon interconnect on an integrated-circuit package substrate according to an embodiment;

FIG. 7B is a cross-section elevation of an integrated-circuit package and a printed wiring board assembly that includes a conductive polygon interconnect on a printed wiring board according to an embodiment;

FIG. 7C is a cross-section elevation of an integrated-circuit package and a printed wiring board assembly that includes a first conductive polygon interconnect on an integrated-circuit package substrate, and a subsequent conductive polygon interconnect on a printed wiring board according to an embodiment;

FIG. 8 is a land side plan of an integrated-circuit substrate with selected conductive polygon interconnects according to several embodiments;

FIG. 9 is a process flow diagram according to several embodiments; and

FIG. 10 is included to show an example of a higher-level device application for the disclosed embodiments.

### DETAILED DESCRIPTION

Disclosed embodiments include conductive polygon interconnects for power and ground supply for integrated-circuit (IC) device packages. First, second and third droop (V_{DD}) responses are mapped against time between about 1 nanosecond (ns) and 100 ns, and use of conductive polygon power interconnects, are retained near the V_{DD} peak after the first droop, compared to conventional ball-grid array interconnects, where power interconnects merely several of the land side interconnects. Further, where the second droop drops conventionally to about one-fourth a useful smoothed droop, the second droop is sustained above about one half the V_{DD} peak after the first droop. Similarly further, where the third droop drops conventionally to about 20 percent the first droop, the third droop is sustained above about two thirds the V_{DD} peak after the first droop.

Passive devices are located between selected power (Vcc) and common-source (Vss) polygon interconnects to facilitate transient current events performance according to an embodiment. Selected conductive polygon interconnects are assembled to IC package substrates according to several embodiments. Selected conductive polygon interconnects are assembled to printed wiring boards for assembly to IC package substrates according to several embodiments. Selected conductive polygon interconnects are assembled to both IC package substrates and to printed wiring boards for joint assembly according to several embodiments.

Arrays of passive devices, such as decoupling capacitors, include multi-layer ceramic capacitors (MLCCs) according to an embodiment. Arrays of passive devices, such as silicon-based capacitors (metal-insulator-metal or MIM) are included according to an embodiment.

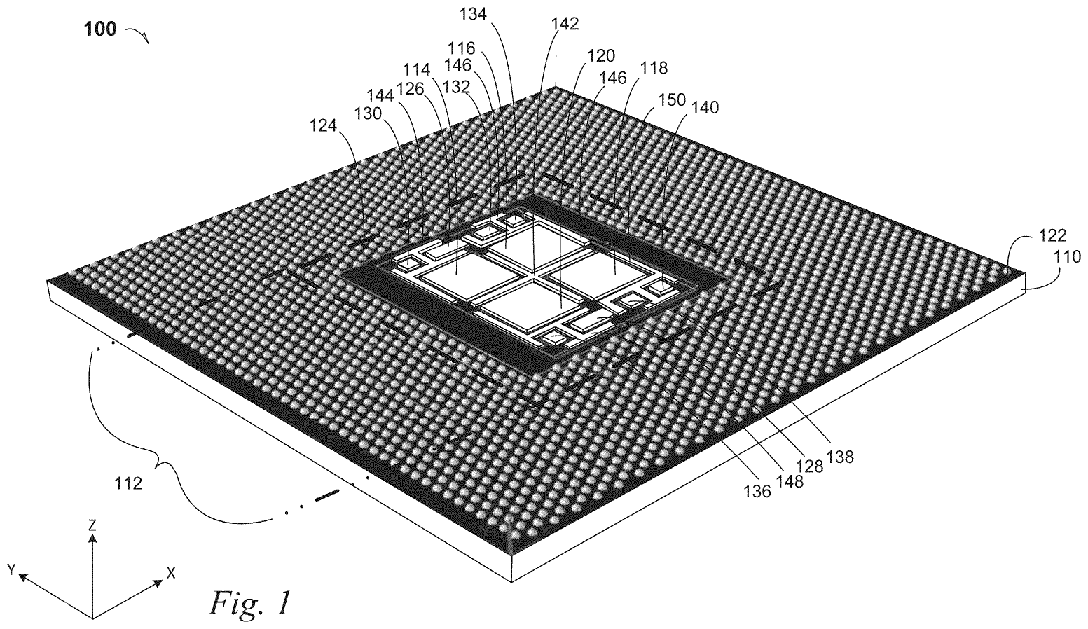

FIG. 1 is a perspective elevation 100 of an integrated-circuit (IC) package substrate 110 with selected conductive polygon interconnects according to several embodiments. In general, the substrate 110 is a printed wiring board. In an embodiment, the substrate 110 is a mother board. In an embodiment, the substrate 110 is an integrated-circuit package substrate 110 with a die side (obscured) and a land side (that carries an electrical contact array 122).

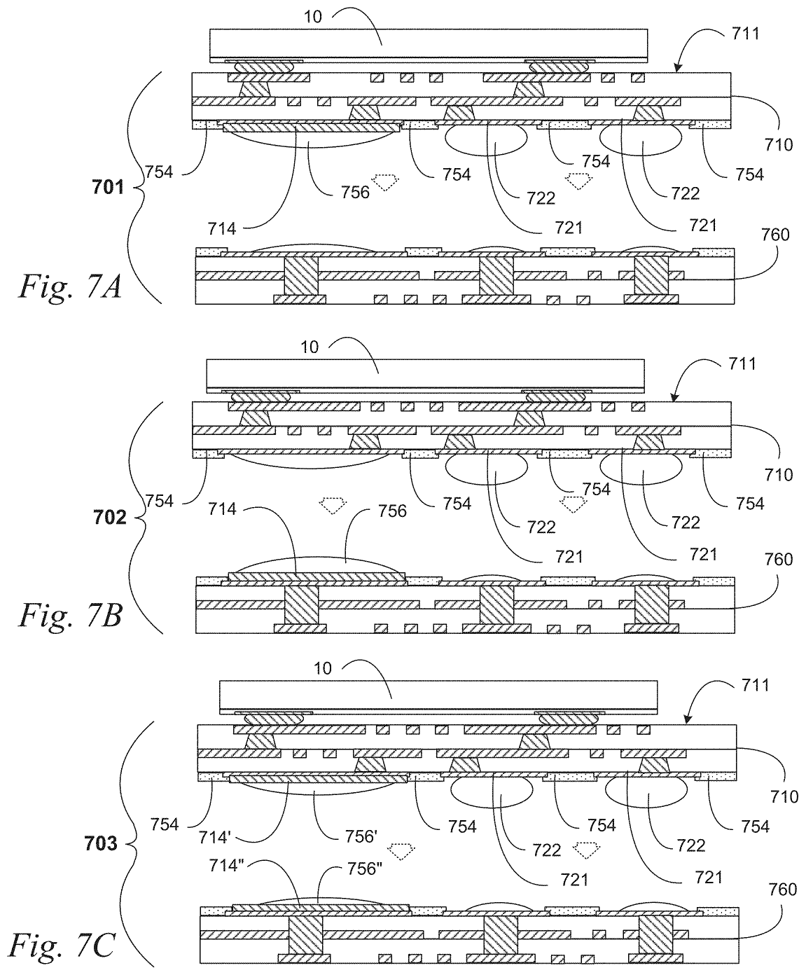

An IC package substrate 110 has an integrated-circuit solder ball footprint 112 that encompasses several conductive polygon interconnects according to an embodiment. In an embodiment, where the substrate 110 is an IC package substrate 110, the IC-die solder ball footprint 112 is being projected from the die surface (obscured by the orientation, and see e.g., the die side 711 in FIGS. 7A, 7B and 7C).

In an embodiment, four primary conductive polygon interconnects 114, 116, 118 and 120 are quadrilaterally symmetrically located within the IC die solder ball footprint 112. In an embodiment, each of the four primary conductive polygon interconnects 114, 116, 118 and 120, are power (Vcc) interconnects.

An electrical interconnect array, such as a ball-grid array (BOA), one electrical ball of which is indicated with reference number 122, surrounds the IC solder ball footprint 112, as well as a portion of the electrical balls that are within the IC solder ball footprint 112. An infield 124 provides a region between conductive polygon interconnects and the several electrical balls of the BOA 122.

In an embodiment, secondary conductive polygon Vcc interconnects 126 and 128 are located near peripheral portions of the IC die solder ball footprint 112, and also near the infield 124. In an embodiment, the secondary conductive polygon interconnects 126 and 128, are Vcc interconnects. In an embodiment, tertiary conductive polygon Vcc interconnects 130, 132, 134, 136, 138 and 140, are smaller than the secondary interconnects. In an embodiment, the tertiary conductive polygon interconnects 130, 132, 134, 136, 138 and 140, are Vcc interconnects.

In general, a conductive polygon form factor is useful for mapping power conduits from, e.g. the first primary conductive polygon power interconnect 114, substantially directly through the printed wiring board 110, to an integrated-circuit die on the die side. The square or rectangular form factor is useful to match the substantially rectangular trace layouts within a given printed wiring board.

Grounding conductive polygon interconnects are provided within the IC solder ball footprint 112 according to several embodiments. In an embodiment, a central conductive polygon interconnect 142 is intersitiated among the four primary conductive polygon interconnects 114, 116, 118 and 120, in a cross form factor. In an embodiment, peripheral conductive polygon interconnects 144, 146, 148 and 150 are interstitiated among the several secondary and tertiary interconnects. In each illustrated embodiment, the peripheral conductive polygon interconnects have portions that are adjacent the primary conductive polygon interconnects, and they have portions that are adjacent the infield 124, as well as portions that are interstitiated with the secondary and tertiary conductive polygon interconnects. In an embodiment, all the conductive polygon Vss interconnects are a single and continuous structure, such that there is a branch among, e.g. the conductive polygon Vss interconnects 142, 144 and 148, as well as a branch among the conductive polygon Vss interconnects 142, 146 and 150.

In general compared to a four-sided (rectangle or quadrilateral) polygon form factor for each of the primary, secondary and tertiary conductive polygon power interconnects, the conductive polygon ground interconnects have orthogonally reticulated form factors. For example, the central conductive polygon interconnect 142 is a cross form factor that is orthogonally reticulated among the four primary conductive polygon interconnects 114, 116, 118 and 120. Similarly for example, the secondary and tertiary conductive polygon interconnects are all four-sided (rectangle or quadrilateral) polygon form factors, and the conductive polygon ground interconnects 144, 146, 148 and 150 are in orthogonally reticulated form factors that are also interstitiated between the primary conductive polygon interconnects and the secondary and tertiary conductive polygon interconnects.

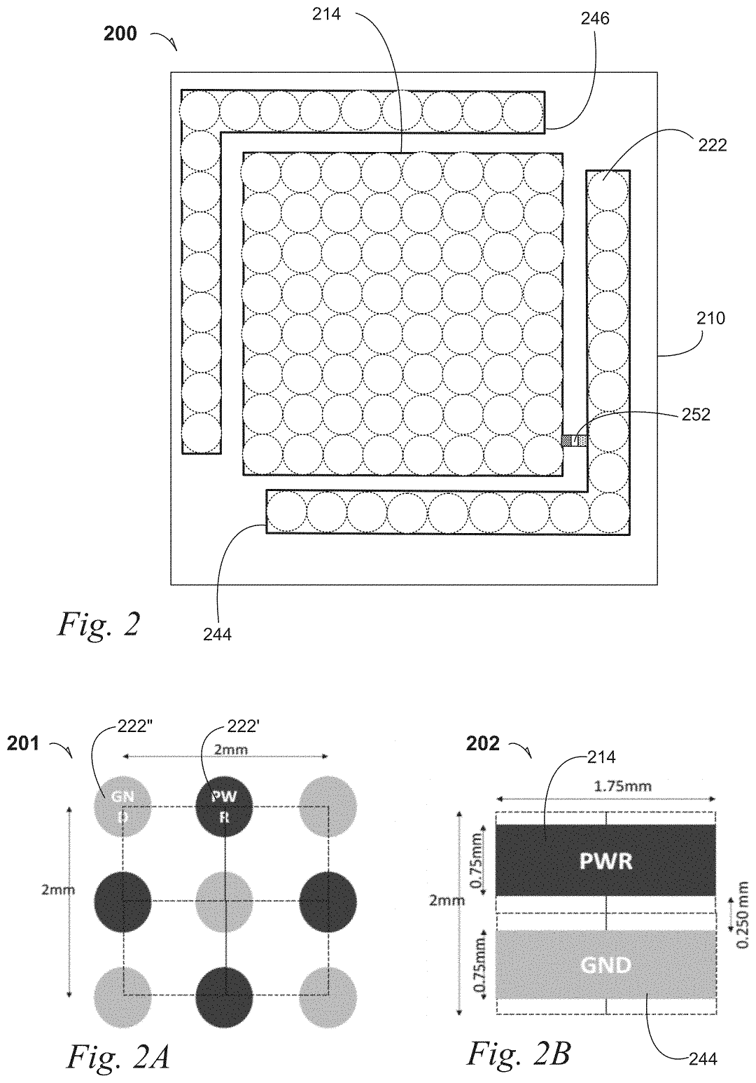

FIG. 2 is a schematic design 200 of a region on an interconnect surface of an integrated-circuit package substrate 210 with a primary conductive polygon interconnect 214 and two conductive polygon Vss interconnects 244 and 246 according to an embodiment. Several equivalent contact area electrical bumps are represented in ghosted lines, one of which is indicated by reference number 222. In the schematic design of conductive polygon interconnects, the equivalent contact area 222 is crowded onto the conductive polygon interconnect footprints, to illustrate concentration of the equivalent contact area 222.

In an embodiment, a passive device 252 is located to bridge between adjacent and spaced-apart power and ground conductive polygon interconnects 214 and 222. In an embodiment, the conductive polygon power interconnect 214 has rectangular form factor, and the conductive polygon ground interconnect 244 has an orthogonally reticulated form factor, at least a portion of which is spaced apart and adjacent the conductive polygon power interconnect 214.

FIGS. 2A and 2B represent a design scheme of conductive polygonal interconnects, where a conventional interconnect layout in FIG. 2A, is designed with disclosed conductive polygon interconnects, such as the interconnects 214, 244 and 246 depicted in FIG. 2 according to an embodiment. For example, in FIG. 2A, four power (PW) 222′ and five ground 222″ interconnects are part of a ball-grid array in a quadrilateral layout. The center-to-center layout is 2 mm². In an embodiment, a redesign scheme illustrated in FIG. 2B, consolidates power and ground interconnects depicted in FIG. 2A, to a conductive polygon Vcc interconnect 214, and a conductive polygon Vss interconnect 244.

In an embodiment, the interconnect 244 only exhibits a portion that is adjacent and spaced apart from the interconnect 214, such that the conductive polygon ground interconnect 244 has an orthogonally reticulated form factor such as the ground interconnects 142 or 144 depicted in FIG. 1.

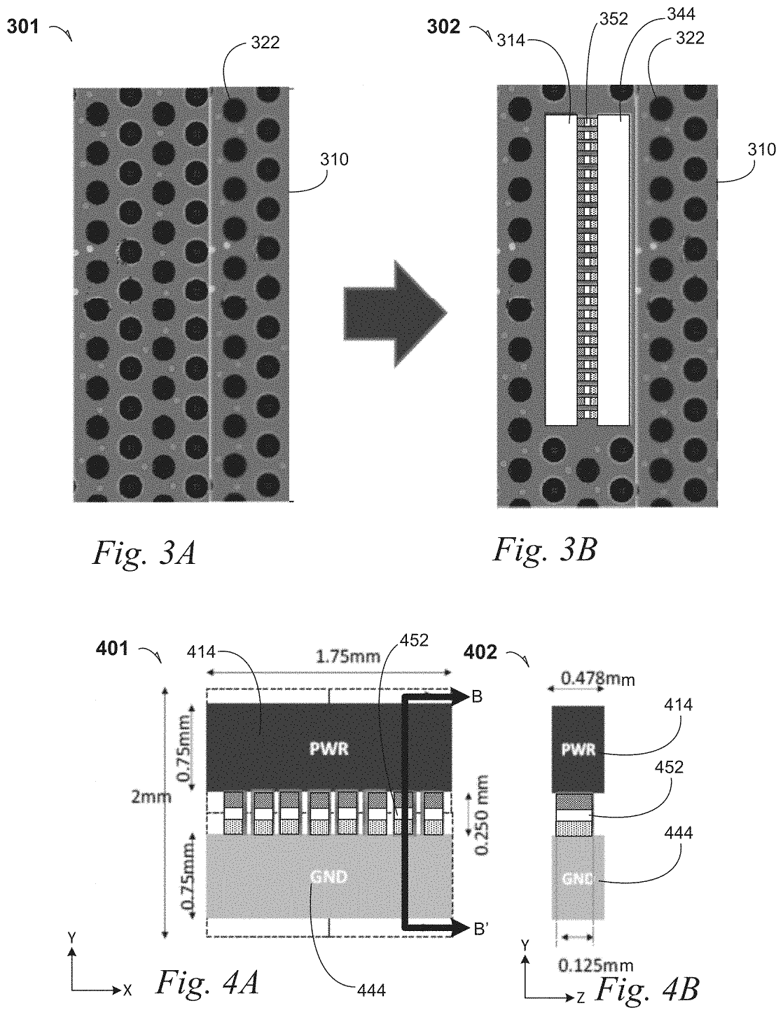

FIGS. 3A and 3B illustrate plan views 301 and 302, respectively, for a design scheme that locates conductive polygon interconnects on a package substrate 310, and connecting at least one passive device across the Vcc and Vss interconnects according to an embodiment.

In FIG. 3A, an interconnect array 301 such as a ball-grid array 322, includes Vss, Vcc and input-output (I/O) interconnects on a portion an IC package substrate 310. In FIG. 3B, several interconnects are removed according to a design-scheme embodiment, and a conductive polygon Vcc interconnect 314, a conductive polygon Vss interconnect 344 are located in a space equivalent from that evacuated in FIG. 3A. Further, at least on passive device 352 is located by bridging between the respective Vcc and Vss conductive polygon interconnects 314 and 344 according to an embodiment. In an embodiment, a plurality of capacitors 352, contact the conductive polygon power interconnect 314 and the conductive polygon ground interconnect 344 by bridging between the interconnects. The plurality is limited by shared adjacent lengths on the interconnects, and individual sizes of the plurality of passive devices 352.

FIGS. 4A and 4B illustrate details of at least one passive device that bridges between respective power and ground conductive polygon interconnects according to an embodiment. In FIG. 4A, an assembly of power conductive polygon interconnect 414 and a ground conductive polygon interconnect 444, are each contacted by at least one passive device 452. In FIG. 4B, a cross-section view is taken along the section line B-B′ according to an embodiment. The assembly 401 depicted in 4A is illustrated. The assembly 402 indicates an elevation view, where the respective conductive polygon interconnects 414 and 444, have a larger Z-dimension than that of the passive device 452 according to an embodiment.

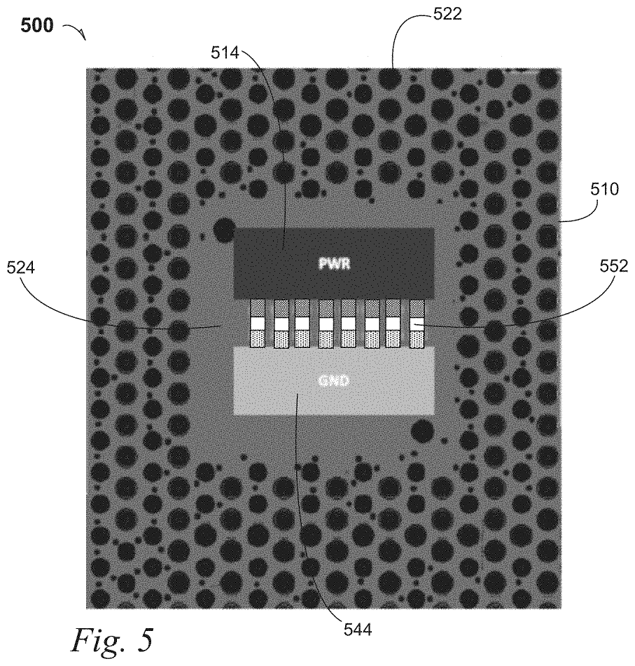

FIG. 5 is a land side plan 500 of an integrated-circuit package substrate 510 that carries a conductive polygon 514 interconnect according to an embodiment. A Vcc conductive polygon interconnect 514 and a Vss conductive polygon interconnect 544 are in an infield 524 created by several electrical bumps 522. In an embodiment, a given region on a package substrate is selected and an infield 524 is designed to be vertically related to an integrated-circuit die, such that the conductive polygons 514 and 544 have adjacent access to the IC die.

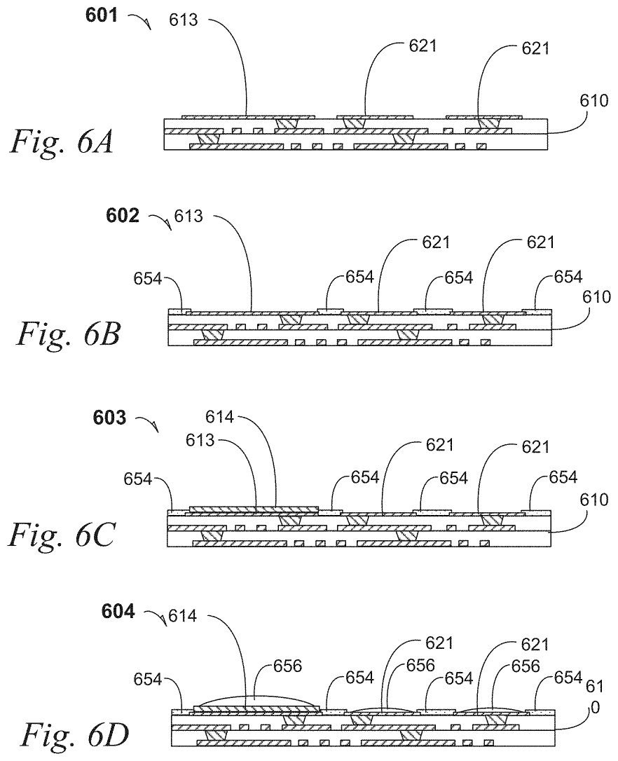

FIGS. 6A through 6D illustrate a process-flow for assembling a conductive polygon interconnect among a ball-grid array on an integrated-circuit package substrate 610 according to several embodiments.

At FIG. 6A, a substrate structure 610, such as a printed wiring board 610, or a package substrate 610 is provided with ball-grid array pads 621 (two occurrences) and an extended interconnect pad 613 according to an embodiment. The ball-grid array pads 621 are configured to accept electrical interconnects such as electrical balls. The extended interconnect pad 613 is configured for further processing to assemble a conductive polygon interconnect.

At FIG. 6B, the substrate structure 610 depicted in FIG. 6A, has been processed to assemble a patterned solder-resist 654 partially overlaps the interconnect pads 613 and 621.

At FIG. 6C, the substrate structure 610 depicted in FIG. 6B, has been processed to assemble a conductive polygon interconnect 614, where plating is conducted on the extended interconnect pad 613 but the ball-grid array pads 621 are masked, followed by mask removal.

At FIG. 6D, the substrate structure 610 depicted in FIG. 6C, has been processed to assemble solder paste 656 onto the vertically extended conductive polygon interconnect 614, as well as to the several ball-grid array pads 621.

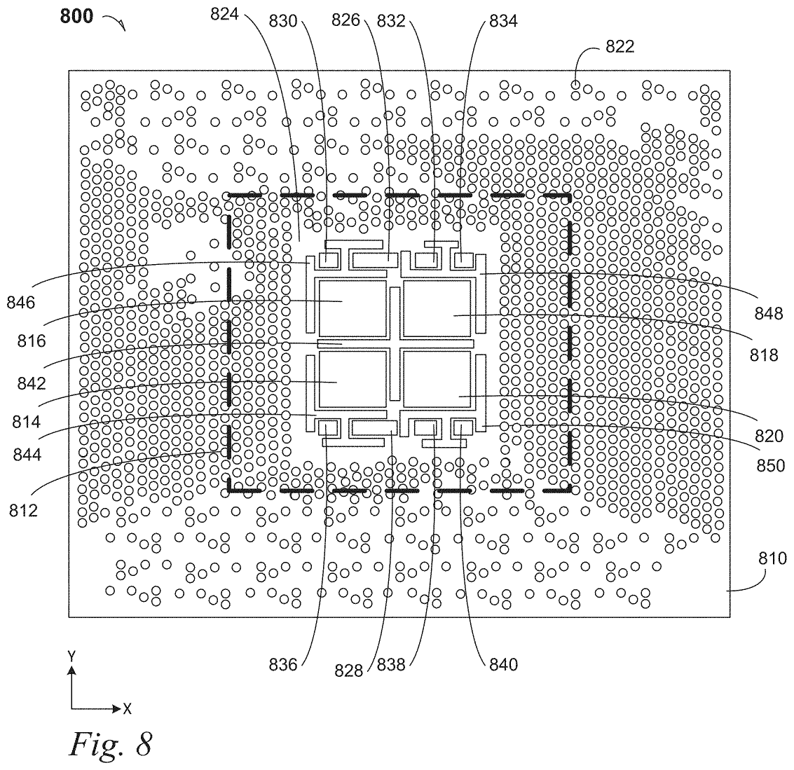

FIG. 7A is a cross-section elevation of an integrated-circuit package and a printed wiring board assembly 701 that includes a conductive polygon interconnect 714 on an integrated-circuit package substrate 710 according to an embodiment. An IC die 10 is flip-chip seated on a die side 711 of the IC package substrate 710. The IC die 10 is a truncated illustration, and it is not to scale for mapping to e.g. the die solder ball footprints 112 and 812 in respective FIGS. 1 and 8.

The IC package substrate 710 is being assembled to a printed wiring board 760, and the IC package substrate 710 has been processed to carry the conductive polygon interconnect 714. The directional arrows indicate the IC package substrate 710 being brought into contact with the printed wiring board 760.

In an embodiment, a solder-paste smear 756 appears on the conductive polygon interconnect 714, and a solder-paste bump 722, or a pre-flowed solder ball 722 appears on a ball-array pad 721, in preparation for forming a ball, e.g., item 122 in FIG. 1.

FIG. 7B is a cross-section elevation of an integrated-circuit package and a printed wiring board assembly 702 that includes a conductive polygon interconnect 714 on a printed wiring board 760 according to an embodiment. An IC die 10 is flip-chip seated on a die side 711 of the IC package substrate 710. The IC die 10 is a truncated illustration, and it is not to scale for mapping to e.g. the die solder ball footprints 112 and 812 in respective FIGS. 1 and 8.

The IC package substrate 710 is being assembled to the printed wiring board 760, and the printed wiring board 760 been processed to carry the conductive polygon interconnect 714. The directional arrows indicate the IC package substrate 710 being brought into contact with the printed wiring board 760.

In an embodiment, a solder-paste smear 756 appears on the conductive polygon interconnect 714 as it has been formed on the printed wiring board, and a solder-paste bump 722, or a pre-flowed solder ball 722 appears on a ball-array pad 721 on the IC package substrate 710, in preparation for forming a ball, e.g., item 122 in FIG. 1.

FIG. 7C is a cross-section elevation of an integrated-circuit package and a printed wiring board assembly 703 that includes a first conductive polygon interconnect 714′ on an integrated-circuit package substrate 710, and a subsequent conductive polygon interconnect 714″ on a printed wiring board 760 according to an embodiment. An IC die 10 is flip-chip seated on a die side 711 of the IC package substrate 710. The IC die 10 is a truncated illustration, and it is not to scale for mapping to e.g. the die solder ball footprints 112 and 812 in respective FIGS. 1 and 8.

The IC package substrate 710 is being assembled to the printed wiring board 760, the IC package substrate 710 has been processed to carry the first conductive polygon interconnect 714′ and the printed wiring board 760 been processed to carry the subsequent conductive polygon interconnect 714″. Each of the respective first and subsequent conductive polygon interconnects 714′ and 714″, have an equivalent half-height or other appropriate ratio of either of the conductive polygon interconnects 714 in FIG. 7A or 7B. The directional arrows indicate the IC package substrate 710 being brought into contact with the printed wiring board 760, and the combined heights of the first and subsequent conductive polygon interconnects 714′ and 714″, create a composite conductive polygon interconnect.

In an embodiment, a solder-paste smear 756″ appears on a conductive polygon interconnect 714″ as it has been formed on the printed wiring board, and a solder-paste smear 756′ has been formed on the IC package substrate 710 on a conductive polygon interconnect 714′ as it has been formed on the IC package substrate 710. Further, a solder-paste bump 722, or a pre-flowed solder ball 722 appears on a ball-array pad 721 on the IC package substrate 710, in preparation for forming a ball, e.g., item 122 in FIG. 1.

FIG. 8 is a land side plan 800 of an integrated-circuit substrate 810 with selected conductive polygon interconnects according to several embodiments. An IC package substrate 810 has an integrated-circuit die solder ball footprint 812 that encompasses several conductive polygon interconnects according to an embodiment. In an embodiment, where the substrate 810 is an IC package substrate 810, the IC-die solder ball footprint 812 is being projected from the die surface (obscured by the orientation, and see e.g., the die side 711 in FIGS. 7A, 7B and 7C).

In an embodiment, four primary conductive polygon interconnects 814, 816, 818 and 820 are quadrilaterally symmetrically located within the IC die solder ball footprint 812. In an embodiment, each of the four primary conductive polygon interconnects 814, 816, 818 and 820, are power (Vcc) interconnects.

A ball-grid array (BGA), one electrical ball of which is indicated with reference number 822, surrounds the IC die solder ball footprint 812, as well as a portion of the electrical balls that are within the IC die footprint 812. The ball-grid array balls 822 are arranged in several patterns and locations on the substrate 810, depending upon specific useful applications of locating IC dice and other devices.

An infield 824 provides a region between conductive polygon interconnects and the several electrical balls of the BOA 822.

In an embodiment, secondary conductive polygon Vcc interconnects 826 and 828 are located near peripheral portions of the IC die footprint 812, and also near the infield 824. In an embodiment, the secondary conductive polygon interconnects 826 and 828, are Vcc interconnects. In an embodiment, tertiary conductive polygon Vcc interconnects 830, 832, 834, 836, 838 and 840, are smaller than the secondary interconnects. In an embodiment, the tertiary conductive polygon interconnects 830, 832, 834, 836, 838 and 840, are Vcc interconnects.

Grounding conductive polygon interconnects are provided within the IC die solder ball footprint 812 according to several embodiments. In an embodiment, a central conductive polygon interconnect 842 is intersitiated among the four primary conductive polygon interconnects 814, 816, 818 and 820, in a cross form factor. In an embodiment, peripheral conductive polygon interconnects 844, 846, 848 and 850 are interstitiated among the several secondary and tertiary interconnects. In each illustrated embodiment, the peripheral conductive polygon interconnects have portions that are adjacent the primary conductive polygon interconnects, and they have portions that are adjacent the infield 824, as well as portions that are interstitiated with the secondary and tertiary conductive polygon interconnects. In an embodiment, all the conductive polygon Vss interconnects are a single and continuous structure, such that there is a branch among, e.g. the conductive polygon Vss interconnects 842, 844 and 848, as well as a branch among the conductive polygon Vss interconnects 842, 846 and 850.

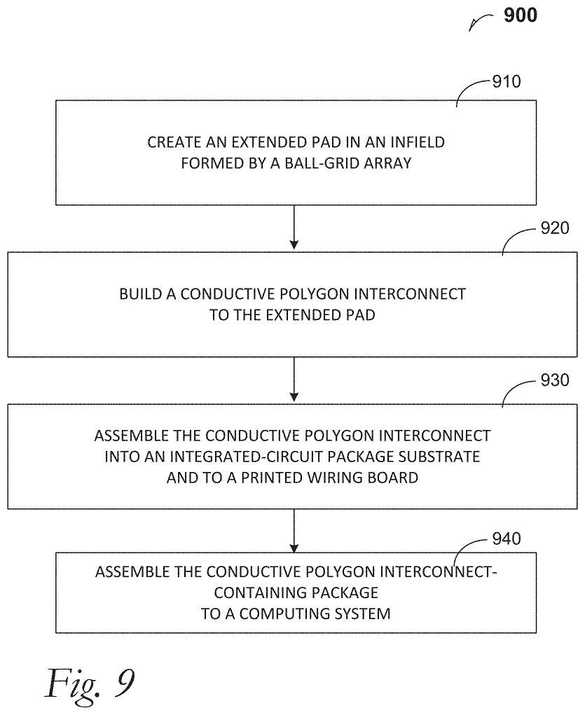

FIG. 9 is a process flow diagram 900 according to several embodiments.

At 910, the process includes assembling an extended pad in an infield that is defined by a ball-grid array. In a non-limiting example embodiment, the extended pad is on an IC package substrate. In a non-limiting example embodiment, the extended pad is on a printed wiring board.

At 920, the process includes assembling a conductive polygon interconnect to the extended pad. In a non-limiting example embodiment, the conductive polygon interconnect is a Vcc interconnect. In a non-limiting example embodiment, the conductive polygon interconnect is a Vss interconnect.

At 930, the process includes assembling the conductive polygon interconnect into an IC package substrate and to a printed wiring board. In a non-limiting example embodiment, the IC package substrate 710 and the printed wiring board 760 are brought together, according to illustrated embodiments in FIG. 7A. In a non-limiting example embodiment, the IC package substrate 710 and the printed wiring board 760 are brought together, according to illustrated embodiments in FIG. 7B. In a non-limiting example embodiment, the IC package substrate 710 and the printed wiring board 760 are brought together, according to illustrated embodiments in FIG. 7C.

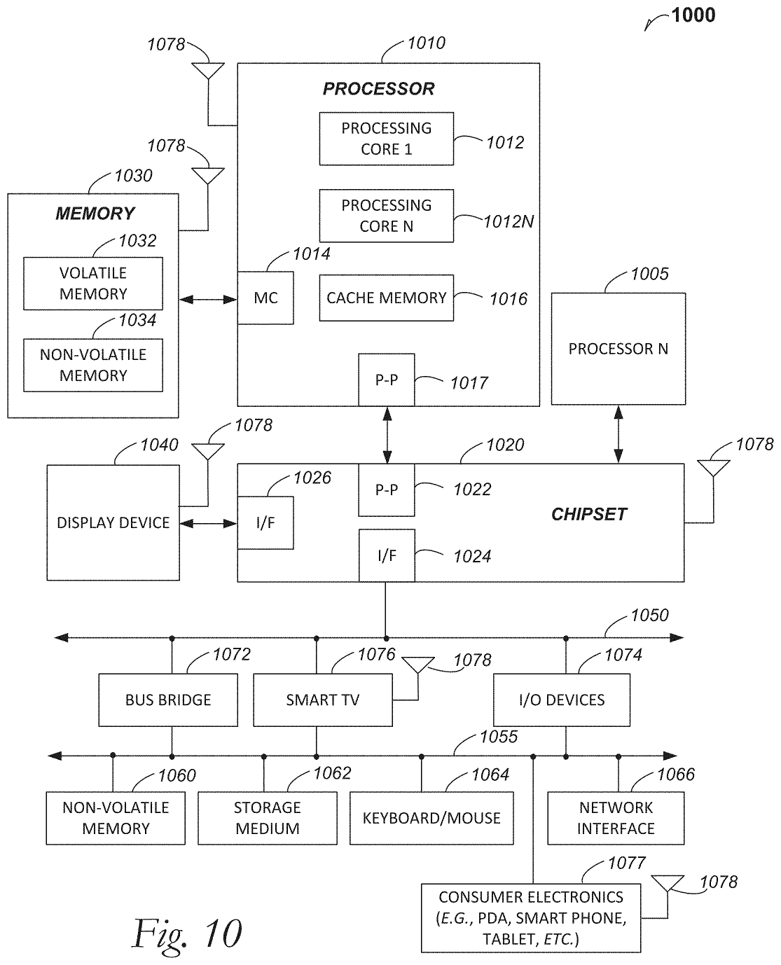

FIG. 10 is included to show an example of a higher-level device application for the disclosed embodiments. The conductive polygon interconnect containing integrated-circuit package embodiments may be found in several parts of a computing system. In an embodiment, the conductive polygon interconnect containing integrated-circuit package embodiments can be part of a communications apparatus such as is affixed to a cellular communications tower. In an embodiment, a computing system 1000 includes, but is not limited to, a desktop computer. In an embodiment, a computing system 1000 includes, but is not limited to a laptop computer. In an embodiment, a computing system 1000 includes, but is not limited to a tablet. In an embodiment, a computing system 1000 includes, but is not limited to a notebook computer. In an embodiment, a computing system 1000 includes, but is not limited to a personal digital assistant (PDA). In an embodiment, a computing system 1000 includes, but is not limited to a server. In an embodiment, a computing system 1000 includes, but is not limited to a workstation. In an embodiment, a computing system 1000 includes, but is not limited to a cellular telephone. In an embodiment, a computing system 1000 includes, but is not limited to a mobile computing device. In an embodiment, a computing system 1000 includes, but is not limited to a smart phone. In an embodiment, a system 1000 includes, but is not limited to an internet appliance. Other types of computing devices may be configured with the microelectronic device that includes conductive polygon interconnect containing integrated-circuit package embodiments.

In an embodiment, the processor 1010 has one or more processing cores 1012 and 1012N, where 1012N represents the Nth processor core inside processor 1010 where N is a positive integer. In an embodiment, the electronic device system 1000 using a conductive polygon interconnect containing integrated-circuit package embodiment that includes multiple processors including 1010 and 1005, where the processor 1005 has logic similar or identical to the logic of the processor 1010. In an embodiment, the processing core 1012 includes, but is not limited to, pre-fetch logic to fetch instructions, decode logic to decode the instructions, execution logic to execute instructions and the like. In an embodiment, the processor 1010 has a cache memory 1016 to cache at least one of instructions and data for the conductive polygon interconnect containing integrated-circuit package element on an integrated-circuit package substrate in the system 1000. The cache memory 1016 may be organized into a hierarchal structure including one or more levels of cache memory.

In an embodiment, the processor 1010 includes a memory controller 1014, which is operable to perform functions that enable the processor 1010 to access and communicate with memory 1030 that includes at least one of a volatile memory 1032 and a non-volatile memory 1034. In an embodiment, the processor 1010 is coupled with memory 1030 and chipset 1020. In an embodiment, the chipset 1020 is part of a conductive polygon interconnect containing integrated-circuit package embodiment depicted, e.g. in the FIGS. 1, 2, 2B, 3B, 4A, 4B, 5, 6D, 7A through 7C and 8.

The processor 1010 may also be coupled to a wireless antenna 1078 to communicate with any device configured to at least one of transmit and receive wireless signals. In an embodiment, the wireless antenna interface 1078 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 1032 includes, but is not limited to, Synchronous Dynamic Random-Access Memory (SDRAM), Dynamic Random-Access Memory (DRAM), RAMBUS Dynamic Random-Access Memory (RDRAM), and/or any other type of random access memory device. The non-volatile memory 1034 includes, but is not limited to, flash memory, phase change memory (PCM), read-only memory (ROM), electrically erasable programmable read-only memory (EEPROM), or any other type of non-volatile memory device.

The memory 1030 stores information and instructions to be executed by the processor 1010. In an embodiment, the memory 1030 may also store temporary variables or other intermediate information while the processor 1010 is executing instructions. In the illustrated embodiment, the chipset 1020 connects with processor 1010 via Point-to-Point (PtP or P-P) interfaces 1017 and 1022. Either of these PtP embodiments may be achieved using a conductive polygon interconnect containing integrated-circuit package embodiment as set forth in this disclosure. The chipset 1020 enables the processor 1010 to connect to other elements in a conductive polygon interconnect containing integrated-circuit package embodiment in a system 1000. In an embodiment, interfaces 1017 and 1022 operate in accordance with a PtP communication protocol such as the Intel® QuickPath Interconnect (QPI) or the like. In other embodiments, a different interconnect may be used.

In an embodiment, the chipset 1020 is operable to communicate with the processor 1010, 1005N, the display device 1040, and other devices 1072, 1076, 1074, 1060, 1062, 1064, 1066, 1077, etc. The chipset 1020 may also be coupled to a wireless antenna 1078 to communicate with any device configured to at least do one of transmit and receive wireless signals.

The chipset 1020 connects to the display device 1040 via the interface 1026. The display 1040 may be, for example, a liquid crystal display (LCD), a plasma display, cathode ray tube (CRT) display, or any other form of visual display device. In an embodiment, the processor 1010 and the chipset 1020 are merged into a conductive polygon interconnect containing integrated-circuit package embodiment in a system. Additionally, the chipset 1020 connects to one or more buses 1050 and 1055 that interconnect various elements 1074, 1060, 1062, 1064, and 1066. Buses 1050 and 1055 may be interconnected together via a bus bridge 1072 such as at least one conductive polygon interconnect containing integrated-circuit package embodiment. In an embodiment, the chipset 1020, via interface 1024, couples with a non-volatile memory 1060, a mass storage device(s) 1062, a keyboard/mouse 1064, a network interface 1066, smart TV 1076, and the consumer electronics 1077, etc.

In an embodiment, the mass storage device 1062 includes, but is not limited to, a solid-state drive, a hard disk drive, a universal serial bus flash memory drive, or any other form of computer data storage medium. In one embodiment, the network interface 1066 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 10 are depicted as separate blocks within the conductive polygon interconnect containing integrated-circuit package embodiments in a computing system 1000, the functions performed by some of these blocks may be integrated within a single semiconductor circuit or may be implemented using two or more separate integrated circuits. For example, although cache memory 1016 is depicted as a separate block within processor 1010, cache memory 1016 (or selected aspects of 1016) can be incorporated into the processor core 1012.

To illustrate the conductive polygon interconnect containing integrated-circuit package IC package embodiments and methods disclosed herein, a non-limiting list of examples is provided herein:

Example 1 is an apparatus, comprising: an integrated-circuit mounting substrate; a conductive polygon power interconnect on the integrated-circuit mounting substrate, wherein the conductive polygon power interconnect is on an extended pad; an electrical interconnect array, wherein the conductive polygon power interconnect is separated from the electrical interconnect array by an infield; a conductive polygon ground interconnect adjacent the conductive polygon power interconnect and separated from the electrical interconnect array by the infield.

In Example 2, the subject matter of Example 1 optionally includes wherein the conductive polygon power interconnect is a rectangle form factor.

In Example 3, the subject matter of any one or more of Examples 1-2 optionally include wherein the conductive polygon power interconnect is one of a plurality of primary conductive polygon power interconnects, wherein the conductive polygon ground interconnect is interstitiated between the plurality of primary conductive polygon power interconnects.

In Example 4, the subject matter of any one or more of Examples 1-3 optionally include wherein the conductive polygon power interconnect is one of a plurality of primary conductive polygon power interconnects, wherein the conductive polygon ground interconnect is orthogonally reticulated and interstitiated between the plurality of primary conductive polygon power interconnects.

In Example 5, the subject matter of any one or more of Examples 1-4 optionally include wherein the conductive polygon power interconnect is one of a plurality of primary conductive polygon power interconnect, wherein the conductive polygon ground interconnect is interstitiated between the plurality of primary conductive polygon power interconnects, further including: a plurality of secondary conductive polygon power interconnects separated from the electrical interconnect array by the infield, wherein the plurality of secondary conductive polygon interconnects are space apart from the plurality of primary conductive polygon interconnects, by conductive polygon ground interconnects.

In Example 6, the subject matter of any one or more of Examples 1-5 optionally include wherein the conductive polygon power interconnect is one of a plurality of primary conductive polygon power interconnect, wherein the conductive polygon ground interconnect is interstitiated between the plurality of primary conductive polygon power interconnects, further including: a plurality of secondary conductive polygon power interconnects separated from the electrical interconnect array by the infield, wherein the plurality of secondary conductive polygon interconnects are space apart from the plurality of primary conductive polygon interconnects, by conductive polygon ground interconnects; and a plurality of tertiary conductive polygon power interconnects separated from the electrical interconnect array by the infield, wherein the plurality of tertiary conductive polygon power interconnects are spaced apart from the plurality of secondary conductive polygon power interconnects by conductive polygon ground interconnects.

In Example 7, the subject matter of any one or more of Examples 1-6 optionally include wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die solder ball footprint on the die side, wherein the solder ball footprint projects to the land side and overshadows the conductive polygon power interconnect, the conductive polygon ground interconnect, a portion of the electrical interconnect array and the infield.

In Example 8, the subject matter of any one or more of Examples 1-7 optionally include wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die solder ball footprint on the die side, wherein the solder ball footprint projects to the land side and overshadows the conductive polygon power interconnect, the conductive polygon ground interconnect, a portion of the electrical interconnect array and the infield, further including an integrated-circuit die on the die side, wherein the integrated-circuit die occupies the footprint.

In Example 9, the subject matter of any one or more of Examples 1-8 optionally include a passive device that contacts the conductive polygon power interconnect and the conductive polygon ground interconnect by bridging between the interconnects.

In Example 10, the subject matter of any one or more of Examples 1-9 optionally include a plurality of capacitor that contact the conductive polygon power interconnect and the conductive polygon ground interconnect by bridging between the interconnects.

In Example 11, the subject matter of Example 10 optionally includes wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die solder ball footprint on the die side, wherein the footprint projects to the land side and overshadows the conductive polygon power interconnect, the conductive polygon ground interconnect, a portion of the electrical interconnect array and the infield.

In Example 12, the subject matter of any one or more of Examples 10-11 optionally include wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die solder ball footprint on the die side, wherein the footprint projects to the land side and overshadows the conductive polygon power interconnect, the conductive polygon ground interconnect, a portion of the electrical interconnect array and the infield, further including an integrated-circuit die on the die side, wherein the integrated-circuit die occupies the footprint.

Example 13 is an integrated-circuit device package, comprising: an integrated-circuit die on a die side of an integrated-circuit package substrate, and wherein the integrated-circuit die projects a footprint onto the integrated-circuit package substrate; a conductive polygon power interconnect within the footprint, wherein the conductive polygon power interconnect is coupled to the integrated-circuit die; a conductive polygon ground interconnect within the footprint, wherein the conductive polygon ground interconnect has an orthogonally reticulated form factor, a portion of which is spaced apart and adjacent the conductive polygon power interconnect; an electrical interconnect array that defines an infield in which the conductive polygon power and ground interconnects are deployed, and wherein the electrical interconnect array is partially within the footprint, and wherein at least a portion of the electrical interconnect array is coupled to the integrated-circuit die, rectilinear is coupled to the integrated-circuit die; and a capacitor contacting and bridging between the conductive polygon power interconnect and the conductive polygon ground interconnect.

In Example 14, the subject matter of Example 13 optionally includes wherein the electrical contact array is a ball-grid array on a ground side of the integrated-circuit package substrate, and wherein the conductive polygon power interconnect and the conductive polygon ground interconnect are on a printed wiring board that contacts the electrical contact array.

In Example 15, the subject matter of any one or more of Examples 13-14 optionally include wherein the electrical contact array is a ball-grid array on a printed wiring board, and wherein the conductive polygon power interconnect and the conductive polygon ground interconnect are on the printed wiring board, and wherein the integrated-circuit package substrate contacts the ball-grid array at a land side that is opposite the die side.

In Example 16, the subject matter of any one or more of Examples 13-15 optionally include a printed wiring board that contacts the electrical bump array at the integrated-circuit package substrate at a land side that is opposite the die side, coupled to the integrated circuit die; and a chipset on the printed wiring board.

Example 17 is a printed wiring board, comprising: four rectangular primary conductive polygon power interconnects on the printed wiring board; a cross form-factor conductive polygon ground interconnect interstitiated among the four rectangular primary conductive polygon power interconnects; a plurality of secondary rectangular conductive polygon power interconnects on the printed wiring board; a plurality of tertiary rectangular conductive polygon power interconnects on the printed wiring board; a plurality of conductive polygon ground interconnects on the printed wiring board, wherein the conductive polygon ground interconnects have orthogonal reticulated form factors, and wherein the plurality of conductive polygon ground interconnects are interstitiated among the secondary and tertiary plurality of conductive polygon ground interconnects and adjacent each of the four primary conductive polygon interconnects.

In Example 18, the subject matter of Example 17 optionally includes an electrical contact array that forms an infield that sets apart the primary, secondary and tertiary conductive polygon power interconnects, and the orthogonal and reticulated conductive polygon ground interconnects.

In Example 19, the subject matter of any one or more of Examples 17-18 optionally include an electrical contact array that forms an infield that sets apart the primary, secondary and tertiary conductive polygon power interconnects, and the orthogonal and reticulated conductive polygon ground interconnects, further including: an integrated-circuit die on a die side of an integrated-circuit package substrate, and wherein the primary, secondary and tertiary conductive polygon power interconnects, and the orthogonal and reticulated conductive polygon ground interconnects, are coupled to the integrated-circuit die.

Example 20 is a process of forming an integrated-circuit mounting substrate, comprising: assembling an extended pad in an infield formed by an electrical-contact array; assembling a conductive polygon power interconnect to the extended pad, wherein the conductive polygon power interconnect has a rectangular form factor; and assembling a conductive polygon ground interconnect adjacent the conductive polygon power interconnect, wherein the conductive polygon ground interconnect has a rectangular reticulated form factor.

In Example 21, the subject matter of Example 20 optionally includes wherein the extended pad is on a land side of an integrated-circuit package substrate, further including: seating the land side onto a printed wiring board by contacting the electrical contact array between the land side and the printed wiring board.

In Example 22, the subject matter of any one or more of Examples 20-21 optionally include wherein the extended pad is on a printed wiring board, further including: seating an integrated-circuit package substrate at a land side onto a printed wiring board by contacting the electrical contact array between the land side and the printed wiring board.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. An apparatus, comprising:
an integrated-circuit mounting substrate;
a conductive polygon power interconnect on the integrated-circuit mounting substrate, wherein the conductive polygon power interconnect is on an extended pad;
an electrical interconnect array, wherein the conductive polygon power interconnect is separated from the electrical interconnect array by an infield;
a conductive polygon ground interconnect adjacent the conductive polygon power interconnect and separated from the electrical interconnect array by the infield.

2. The apparatus of claim 1, wherein the conductive polygon power interconnect is a rectangle form factor.

3. The apparatus of claim 1, wherein the conductive polygon power interconnect is one of a plurality of primary conductive polygon power interconnects, wherein the conductive polygon ground interconnect is interstitiated between the plurality of primary conductive polygon power interconnects.

4. The apparatus of claim 1, wherein the conductive polygon power interconnect is one of a plurality of primary conductive polygon power interconnects, wherein the conductive polygon ground interconnect is orthogonally reticulated and interstitiated between the plurality of primary conductive polygon power interconnects.

5. The apparatus of claim 1, wherein the conductive polygon power interconnect is one of a plurality of primary conductive polygon power interconnect, wherein the conductive polygon ground interconnect is interstitiated between the plurality of primary conductive polygon power interconnects, further including:
a plurality of secondary conductive polygon power interconnects separated from the electrical interconnect array by the infield, wherein the plurality of secondary conductive polygon interconnects are space apart from the plurality of primary conductive polygon interconnects, by conductive polygon ground interconnects.

6. The apparatus of claim 1, wherein the conductive polygon power interconnect is one of a plurality of primary conductive polygon power interconnect, wherein the conductive polygon ground interconnect is interstitiated between the plurality of primary conductive polygon power interconnects, further including:
a plurality of secondary conductive polygon power interconnects separated from the electrical interconnect array by the infield, wherein the plurality of secondary conductive polygon interconnects are space apart from the plurality of primary conductive polygon interconnects, by conductive polygon ground interconnects; and
a plurality of tertiary conductive polygon power interconnects separated from the electrical interconnect array by the infield, wherein the plurality of tertiary conductive polygon power interconnects are spaced apart from the plurality of secondary conductive polygon power interconnects by conductive polygon ground interconnects.

7. The apparatus of claim 1, wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die footprint on the die side, wherein the footprint projects to the land side and overshadows the conductive polygon power interconnect, the conductive polygon ground interconnect, a portion of the electrical interconnect array and the infield.

8. The apparatus of claim 1, wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die footprint on the die side, wherein the footprint projects to the land side and overshadows the conductive polygon power interconnect, the conductive polygon ground interconnect, a portion of the electrical interconnect array and the infield, further including an integrated-circuit die on the die side, wherein the integrated-circuit die occupies the footprint.

9. The apparatus of claim 1, further including a passive device that contacts the conductive polygon power interconnect and the conductive polygon ground interconnect by bridging between the interconnects.

10. The apparatus of claim 1, further including a plurality of capacitor that contact the conductive polygon power interconnect and the conductive polygon ground interconnect by bridging between the interconnects.

11. The apparatus of claim 10, wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die footprint on the die side, wherein the footprint projects to the land side and overshadows the conductive polygon power interconnect, the conductive polygon ground interconnect, a portion of the electrical interconnect array and the infield.

12. The apparatus of claim 10, wherein the integrated-circuit mounting substrate is an integrated-circuit package substrate with a die side and a land side, wherein land side carries the conductive polygon power interconnect, the conductive polygon ground interconnect, the electrical interconnect array and the infield, further including an integrated-circuit die footprint on the die side, wherein the footprint projects to the land side and overshadows the conductive polygon power interconnect, the conductive polygon ground interconnect, a portion of the electrical interconnect array and the infield, further including an integrated-circuit die on the die side, wherein the integrated-circuit die occupies the footprint.

13. An integrated-circuit device package, comprising:
an integrated-circuit die on a die side of an integrated-circuit package substrate, and wherein the integrated-circuit die projects a footprint onto the integrated-circuit package substrate;
a conductive polygon power interconnect within the footprint, wherein the conductive polygon power interconnect is coupled to the integrated-circuit die;
a conductive polygon ground interconnect within the footprint, wherein the conductive polygon ground interconnect has an orthogonally reticulated form factor, a portion of which is spaced apart and adjacent the conductive polygon power interconnect;
an electrical interconnect array that defines an infield in which the conductive polygon power and ground interconnects are deployed, and wherein the electrical interconnect array is partially within the footprint, and wherein at least a portion of the electrical interconnect array is coupled to the integrated-circuit die, rectilinear is coupled to the integrated-circuit die; and
a capacitor contacting and bridging between the conductive polygon power interconnect and the conductive polygon ground interconnect.

14. The integrated-circuit package of claim 13, wherein the electrical contact array is a ball-grid array on a ground side of the integrated-circuit package substrate, and wherein the conductive polygon power interconnect and the conductive polygon ground interconnect are on a printed wiring board that contacts the electrical contact array.

15. The integrated-circuit package of claim 13, wherein the electrical contact array is a ball-grid array on a printed wiring board, and wherein the conductive polygon power interconnect and the conductive polygon ground interconnect are on the printed wiring board, and wherein the integrated-circuit package substrate contacts the ball-grid array at a land side that is opposite the die side.

16. The integrated-circuit package of claim 13, further including:
a printed wiring board that contacts the electrical bump array at the integrated-circuit package substrate at a land side that is opposite the die side, coupled to the integrated circuit die; and
a chipset on the printed wiring board.

17. A printed wiring board, comprising:
four rectangular primary conductive polygon power interconnects on the printed wiring board;
a cross form-factor conductive polygon ground interconnect interstitiated among the four rectangular primary conductive polygon power interconnects;
a plurality of secondary rectangular conductive polygon power interconnects on the printed wiring board;
a plurality of tertiary rectangular conductive polygon power interconnects on the printed wiring board;
a plurality of conductive polygon ground interconnects on the printed wiring board, wherein the conductive polygon ground interconnects have orthogonal reticulated form factors, and wherein the plurality of conductive polygon ground interconnects are interstitiated among the secondary and tertiary plurality of conductive polygon ground interconnects and adjacent each of the four primary conductive polygon interconnects.

18. The printed wiring board of claim 17, further including an electrical contact array that forms an infield that sets apart the primary, secondary and tertiary conductive polygon power interconnects, and the orthogonal and reticulated conductive polygon ground interconnects.

19. The printed wiring board of claim 17, further including an electrical contact array that forms an infield that sets apart the primary, secondary and tertiary conductive polygon power interconnects, and the orthogonal and reticulated conductive polygon ground interconnects, further including:
an integrated-circuit die on a die side of an integrated-circuit package substrate, and wherein the primary, secondary and tertiary conductive polygon power interconnects, and the orthogonal and reticulated conductive polygon ground interconnects, are coupled to the integrated-circuit die.

20. A process of forming an integrated-circuit mounting substrate, comprising:
assembling an extended pad in an infield formed by an electrical-contact array;
assembling a conductive polygon power interconnect to the extended pad, wherein the conductive polygon power interconnect has a rectangular form factor; and
assembling a conductive polygon ground interconnect adjacent the conductive polygon power interconnect, wherein the conductive polygon ground interconnect has a rectangular reticulated form factor.

21. The process of claim 20, wherein the extended pad is on a land side of an integrated-circuit package substrate, further including:
seating the land side onto a printed wiring board by contacting the electrical contact array between the land side and the printed wiring board.

22. The process of claim 20, wherein the extended pad is on a printed wiring board, further including:
seating an integrated-circuit package substrate at a land side onto a printed wiring board by contacting the electrical contact array between the land side and the printed wiring board.
